(19) United States
(12) Patent Application Publication
(10) Pub. No.: US 2011/0115030 A1
(43) Pub. Date: May 19, 2011

(54) SEMICONDUCTOR DEVICE

(75) Inventor: Yoji KITANO, Chino (JP)

(73) Assignee: SEIKO EPSON CORPORATION, Tokyo (JP)

(21) Appl. No.: 12/946,046

(22) Filed: Nov. 15, 2010

(30) Foreign Application Priority Data
Nov. 16, 2009 (JP) 2009-260838

(51) Int. Cl. H01L 27/088

(52) U.S. Cl. 257/392; 257/E27.061

(57) ABSTRACT

A semiconductor device includes: a partially depleted first transistor formed in a semiconductor layer on an insulating layer; a second transistor formed in the semiconductor layer; and a third transistor formed in the semiconductor layer, wherein the first transistor has a first gate electrode formed above the semiconductor layer via an insulating film and a first source or a first drain of a first conductivity type formed in the semiconductor layer below a side of the first gate electrode, the second transistor has a second gate electrode formed above the semiconductor layer via the insulating film and a second source or a second drain of the first conductivity type formed in the semiconductor layer below a side of the second gate electrode, the third transistor has a third gate electrode formed above the semiconductor layer via the insulating film and a third source or a third drain of a second conductivity type formed in the semiconductor layer below a side of the third gate electrode, one of the first source and the first drain and one of the second source and the second drain are electrically connected, and the other of the second source and the second drain, a region of the semiconductor layer just below the first gate electrode, and one of the third source and the third drain are electrically connected to one another.

### BACKGROUND

1. Technical Field

The present invention relates to a semiconductor device including a partially depleted transistor in a semiconductor layer on an insulating layer.

2. Related Art

A technique of forming a semiconductor device in a thin semiconductor film formed on an insulating film (silicon on insulator (SOI)) has been developed and put to practical use as a low-power semiconductor device in the next generation. The SOI has advantages such as a high ON/OFF ratio or steep subthreshold characteristic of a drain current, low noise, and a low parasitic capacitance, and the application thereof to integrated circuits used for watches, mobile devices, and the like is progressing. At present, a metal insulator semiconductor field effect transistor (MISFET) having an SOI structure is used for various semiconductor integrated circuits. Especially a MISFET having a partially depleted (PD) SOI structure (hereinafter referred to as a PD-SOI MISFET) that can be manufactured easily in the same manner as a method for manufacturing a MISFET having a bulk structure in the related art is widely applied to semiconductor products. The structure of the PD-SOI MISFET is disclosed in, for example, JP-A-2004-128254.

In the PD-SOI MISFET, a body region is electrically isolated from other regions by means of an element isolation film and an insulating layer (also referred to as a BOX layer), and the potential of the body region (that is, a body potential) floats. Therefore, the influence of a phenomenon called a substrate floating effect on device characteristics (for example, a history effect) has to be considered. The history effect is a phenomenon in which a body potential and a drain current fluctuate due to the history of voltage having been applied to a gate, a drain, and a source, causing unstable device characteristics.

The history effect can be suppressed by a known body potential fixing method shown in, for example, FIGS. 18A and 18B.

FIGS. 18A and 18B are respectively a plan view and a cross-sectional view showing a configuration example of a PD-SOI MISFET 90 according to the related art. In FIG. 18A, an inter-layer insulating film is omitted from the illustration for avoiding complication of the drawing.

As shown in FIGS. 18A and 18B, the PD-SOI MISFET 90 has a gate insulating film 93 formed on the surface of an SOI layer 92 on a BOX layer 91, a gate electrode 94 formed above the SOI layer 92 via the gate insulating film 93, an N-type source 95a or an N-type drain 95b formed in the SOI layer 92 below both sides of the gate electrode 94, and a P⁺ layer 96 connected to the SOI layer (that is, a body region) 92 in a region just below the gate electrode 94.

In the PD-SOI MISFET 90, a depletion layer 92a does not reach the BOX layer 91, and a neutral region 92b is left, during its operation as shown in FIG. 18B. Since the potential of the body region 92 (that is, a body potential) is fixed to a desired potential (for example, a ground potential) via a contact electrode 97 and the P⁺ layer 96, the substrate floating effect is suppressed, and the history effect is suppressed. Such a structure is called body contact, or also called body tie, which is disclosed in, for example, JP-A-2004-119884.

In the PD-SOI MISFET 90, when the body potential is fixed (that is, in the case of the body contact), device characteristics become stable, but on the other hand, a parasitic capacitance is generated in the body region. Therefore, an ON current is decreased, leading to a problem of a decrease in ON/OFF ratio or increase in subthreshold swing value (S value) of a drain current. That is, there is a problem in that the drive current of the PD-SOI MISFET 90 is decreased, whereby the current drive ability thereof becomes substantially equal to that of bulk silicon. Therefore, in the structure shown in FIGS. 18A and 18B, it might be impossible to make full use of the advantages of the SOI.

### SUMMARY

An advantage of some aspects of the invention is to provide a semiconductor device in which a high ON/OFF ratio, that is, a low S value and stable operation can be realized simultaneously in a partially depleted transistor formed in a semiconductor layer on an insulating layer.

An aspect of the invention is directed to a semiconductor device including: a partially depleted first transistor formed in a semiconductor layer on an insulating layer; a second transistor formed in the semiconductor layer; and a third transistor formed in the semiconductor layer, wherein the first transistor has a first gate electrode formed above the semiconductor layer via an insulating film and a first source or a first drain of a first conductivity type formed in the semiconductor layer below a side of the first gate electrode, the second transistor has a second gate electrode formed above the semiconductor layer via the insulating film and a second source or a second drain of the first conductivity type formed in the semiconductor layer below a side of the second gate electrode, the third transistor has a third gate electrode formed above the semiconductor layer via the insulating film and a third source or a third drain of a second conductivity type formed in the semiconductor layer below a side of the third gate electrode, one of the first source and the first drain and one of the second source and the second drain are electrically connected, and the other of the second source and the second drain, a region of the semiconductor layer just below the first gate electrode, and one of the third source and the third drain are electrically connected to one another.

Here, the “insulating layer” is also called a BOX layer, for example, and the “semiconductor layer” is also called an SOI layer, for example. The “partially depleted transistor” is a transistor in which during the operation of the transistor, a semiconductor layer (that is, a body region) in a region just below a gate electrode is not completely depleted but partially depleted (that is, a depletion layer does not reach an insulating layer, and a neutral region is left). The “insulating film” between the first gate electrode, the second gate electrode, or the third gate electrode and the semiconductor layer may be a gate oxide film formed by thermal oxidation of the semiconductor layer or may be another insulating film (for example, a high-k film).

With this configuration, when the first transistor is ON, the second transistor is turned ON, and the third transistor can be turned OFF. Therefore, the body region of the first transistor can be electrically disconnected from a fixed potential such as VSS (or GND) or VDD, for example. In this case, when the first conductivity type is N-type, and the second conductivity type is P-type (that is, when the first and second transistors are N-channel transistors, and the third transistor is a P-channel transistor), part of an ON current that should flow between the source and drain of the first transistor can flow into the body region of the first transistor (that is, a first body region) through a channel of the second transistor.

When the first conductivity type is P-type, and the second conductivity type is N-type (that is, when the first and second transistors are P-channel transistors, and the third transistor is an N-channel transistor), the part of the ON current that should flow between the source and drain of the first transistor can flow out of the source of the first transistor through the body region of the first transistor (that is, the first body region) and flow into the drain of the first transistor through the channel of the second transistor.

When the first and second transistors are N-channel transistors, and the third transistor is a P-channel transistor, the potential of the first body region increases due to the flowing current, and therefore a threshold voltage of the first transistor decreases. As a result, the ON current of the first transistor increases. Such a decrease in threshold voltage and an increase in ON current in response to the decrease cease when there is no difference between the amount of charge (hole in this case) flowing into the first body region through the second transistor and the amount of charge flowing out of the first body region into the first source (that is, when they are balanced). At this point of time, the potential of the first body region is stabilized.

When the first and second transistors are P-channel transistors, and the third transistor is an N-channel transistor, the change in potential of the body region is reversed from that in the above description. That is, due to the current flowing out of the first body region, the potential of the first body region decreases; the absolute value of the threshold voltage of the first transistor decreases; and the ON current of the first transistor increases. Such a decrease in absolute value of the threshold voltage and an increase in ON current in response to the decrease cease when there is no difference between the amount of charge (electron in this case) flowing into the first body region through the second transistor and the amount of charge flowing out of the first body region into the first source. At this point of time, the potential of the first body region is stabilized.

In this manner, when the first transistor is ON, the ON current of the first transistor can be increased due to the effect of body bias. Not only merely the effect of body bias but also the part of the ON current is used to increase (or decrease) the potential of the first body region, and therefore the threshold voltage (or the absolute value of the threshold voltage) of the first transistor is decreased. Therefore, the ON current of the first transistor can be increased without waste.

On the other hand, when the first transistor is OFF, the second transistor is turned OFF, and the third transistor can be turned ON. Therefore, the first transistor can be made into the body contact structure (that is, the potential of the body region can be fixed). When the first transistor is OFF, the potential of the first body region is reset due to the effect of body contact. Therefore, the history effect in the first transistor is suppressed, and the OFF current of the first transistor can be decreased. That is, when the first transistor is ON, charge is injected or released through the second transistor, so that the body potential of the first transistor increases (decreases in the case of a P-channel transistor) and the threshold voltage is in a low state. Whereas, when the first transistor is turned OFF, the third transistor is turned ON, so that the body potential of the first transistor can be fixed in a low state (high state in the case of a P-channel transistor), that is, the threshold voltage can be fixed in a high state. Therefore, the OFF current of the first transistor can be decreased.

In this manner, in accordance with the ON and OFF of the first transistor, the body bias state and the body contact state can be switched. In addition, when the first transistor is ON, the threshold voltage (or the absolute value of the threshold voltage) of the first transistor can be decreased using the part of the ON current, and when OFF, the threshold voltage can be increased due to the body contact. Therefore, compared to the technique of the related art, a high ON/OFF ratio, that is, a low S value and stable operation can be realized simultaneously.

The semiconductor device may be configured such that when a first voltage is applied to the first gate electrode, the second gate electrode, and the third gate electrode, the first transistor and the second transistor are turned on, and the third transistor is turned off, while when a second voltage is applied to the first gate electrode, the second gate electrode, and the third gate electrode, the first transistor and the second transistor are turned off, and the third transistor is turned on.

The semiconductor device may be configured such that the second transistor is a partially depleted transistor. With this configuration for example, the first transistor and the second transistor can be formed in the same process simultaneously. Therefore, the configuration can contribute to a decrease in the number of processing steps and a decrease in manufacturing cost. Moreover, since the first transistor and the second transistor can be formed adjacent to each other in the semiconductor layer of the same thickness for example, the layout efficiency is also high.

The semiconductor device may be configured such that a region of the semiconductor layer just below the second gate electrode is electrically connected to the other of the second source and the second drain. With this configuration, when the first transistor is ON, the part of the ON current that should flow into the channel of the first transistor can flow not only into the first body region but also the body region of the second transistor (that is, a second body region) through the channel of the second transistor. Due to the flowing current, the potential of the second body region increases (or decreases) together with the potential of the first body region, and the threshold voltage (or the absolute value of the threshold voltage) of the second transistor decreases. Thus, the ON current of the second transistor can be increased, and the current flowing into the first body region can be further increased.

The semiconductor device may be configured such that the first gate electrode, the second gate electrode, and the third gate electrode are electrically connected to one another. With this configuration, a contact electrode can be used in common, so that the number of contact electrodes can be decreased. This makes it possible to contribute to a decrease in area of the element. Moreover, it becomes easy to apply a voltage of the same magnitude to each of the gate electrodes at the same timing.

The semiconductor device may be configured such that the semiconductor device further includes a first impurity diffusion layer of the first conductivity type formed in the semiconductor layer, and that the first impurity diffusion layer is one of the first source and the first drain and also as one of the second source and the second drain. With this configuration, the first source and the second source, or the first drain and the second drain can be shared through one first impurity diffusion layer. Therefore, the configuration can contribute to a decrease in area of the element.

The semiconductor device may be configured such that the semiconductor device further includes a second impurity diffusion layer of the first conductivity type formed in the semiconductor layer and a third impurity diffusion layer of the second conductivity type formed in the semiconductor layer, that the second impurity diffusion layer is the other of the first source and the first drain, that the third impurity diffusion layer is the other of the third source and the third drain, that the third impurity diffusion layer and the first impurity diffusion layer are electrically isolated from each other, and that the third impurity diffusion layer and the second impurity diffusion layer are electrically isolated from each other. This configuration can contribute to a decrease in parasitic capacitance of the first transistor.

The semiconductor device may be configured such that the semiconductor device further includes a fourth impurity diffusion layer of the first conductivity type formed in the semiconductor layer and a fifth impurity diffusion layer of the second conductivity type formed in the semiconductor layer, that the fourth impurity diffusion layer is the other of the second source and the second drain, that the fifth impurity diffusion layer is one of the third source and the third drain, and that the electrical connection between the fourth impurity diffusion layer and the fifth impurity diffusion layer is made with a compound layer of the semiconductor layer and metal formed continuously from the fourth impurity diffusion layer to the fifth impurity diffusion layer. In this case for example, when the semiconductor layer is silicon, the compound layer is silicide. Even with this configuration, the part of the ON current that should flow into the channel of the first transistor can flow into the first body region of the first transistor through the compound layer.

### BRIEF DESCRIPTION OF THE DRAWINGS

The invention will be described with reference to the accompanying drawings, wherein like numbers reference like elements.

FIG. 1 is a diagram showing a configuration example of a circuit of a semiconductor device according to a first embodiment of the invention.

FIGS. 2A to 2C are diagrams showing a configuration example of the semiconductor device according to the first embodiment of the invention.

FIGS. 3A to 3C are diagrams showing arrangement examples of respective transistors.

FIG. 4 is a graph showing transfer characteristics of the respective transistors.

FIGS. 5A and 5B are diagrams showing a method for manufacturing the semiconductor device according to the first embodiment of the invention.

FIGS. 6A and 6B are diagrams showing the method for manufacturing the semiconductor device according to the first embodiment of the invention.

FIGS. 7A and 7B are diagrams showing the method for manufacturing the semiconductor device according to the first embodiment of the invention.

FIGS. 8A and 8B are diagrams showing the method for manufacturing the semiconductor device according to the first embodiment of the invention.

FIGS. 9A and 9B are diagrams showing the method for manufacturing the semiconductor device according to the first embodiment of the invention.

FIGS. 10A and 10B are diagrams showing the method for manufacturing the semiconductor device according to the first embodiment of the invention.

FIGS. 11A and 11B are diagrams showing the method for manufacturing the semiconductor device according to the first embodiment of the invention.

FIGS. 12A to 12C are diagrams showing a configuration example of a semiconductor device according to a second embodiment of the invention.

FIGS. 13A and 13B are diagrams showing a configuration example of a semiconductor device according to a third embodiment of the invention.

FIG. 14 is a diagram showing another configuration example of the semiconductor device according to the third embodiment of the invention.

FIGS. 15A to 15C are diagrams showing a configuration example of a semiconductor device according to a fourth embodiment of the invention.

FIG. 16 is a diagram showing a configuration example of a circuit of a semiconductor device according to a fifth embodiment of the invention.

FIGS. 17A to 17C are diagrams showing a configuration example of the semiconductor device according to the fifth embodiment of the invention.

FIGS. 18A and 18B are diagrams showing a configuration example of a semiconductor device according to the related art.

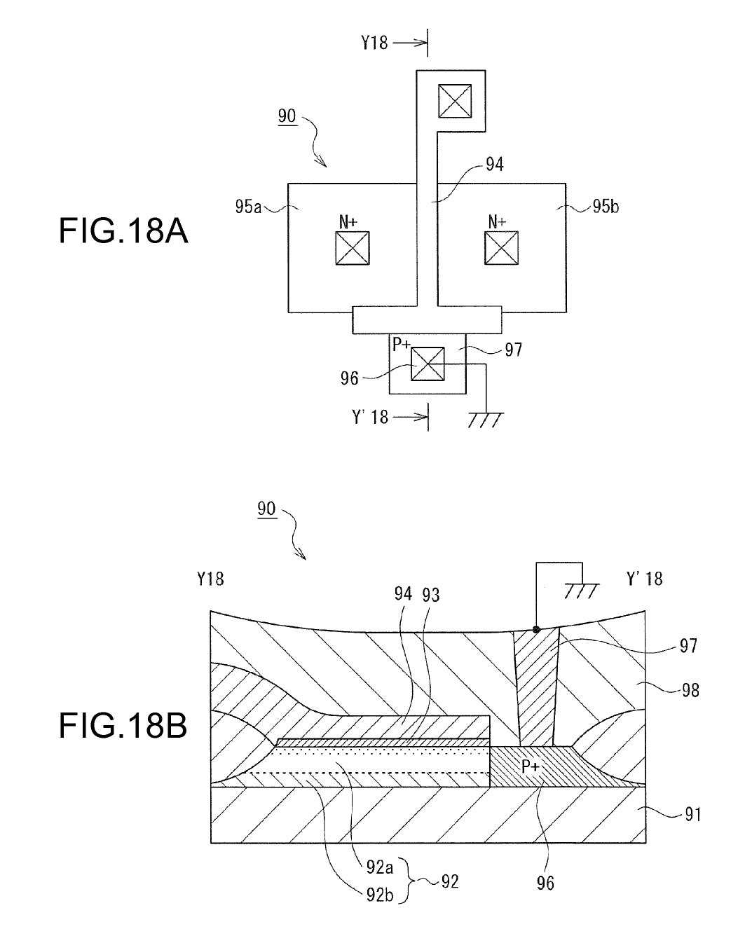

FIG. 19 is a graph schematically showing a change in Vth due to impact ionization.

### DESCRIPTION OF EXEMPLARY EMBODIMENTS

Hereinafter, embodiments of the invention will be described with reference to the drawings. In the drawings described below, portions having the same configuration are denoted by the same reference numeral and sign, and the repetitive description thereof is omitted. In the following description, the description will be made on the assumption that the side on which wiring 43a to 43e are present is the upper side, and that the side on which a BOX layer 1 is present is the lower side, when referring to the vertical direction.

### 1 First Embodiment

### Configuration Example of Semiconductor Device

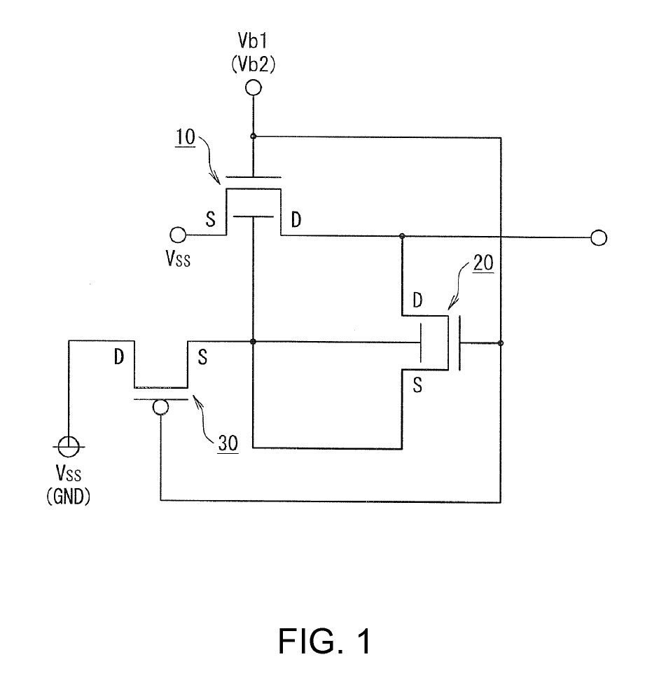

FIG. 1 is a circuit diagram showing a configuration example of a semiconductor device according to a first embodiment of the invention. As shown in FIG. 1, the semiconductor device is configured to include an N-channel first transistor 10, an N-channel second transistor 20, and a P-channel third transistor 30. Each of the first transistor 10, the second transistor 20, and the third transistor 30 is a partially depleted MIS transistor that is formed in an SOI layer on a BOX layer. The BOX layer is a silicon oxide film (SiO₂), for example, and the SOI layer is a single-crystal silicon layer (Si), for example. Alternatively, the SOI layer may be so-called strained silicon having a stacked structure of, for example, Si and SiGe (that is, an Si—SiGe structure).

In FIG. 1, the connection relationship among the first transistor 10, the second transistor 20, and the third transistor 30 will be described. A drain (D) of the first transistor 10 and a drain of the second transistor 20 are electrically connected. A source (S) of the second transistor 20, a region (that is, a first body region) of the SOI layer just below a gate electrode of the first transistor 10, a region (that is, a second body region) of the SOI layer just below a gate electrode of the second transistor 20, and a source of the third transistor 30 are electrically connected to one another. Moreover, a source of the first transistor 10 is connected to a first constant-potential power supply line (for example, VSS), and a drain of the third transistor 30 is connected to a second constant-potential power supply line (for example, GND or VSS). GND is a ground potential, and VSS is a constant potential that is positive or negative, or zero.

In the semiconductor device for example, when a positive bias (a first voltage) Vb1 of the same magnitude is applied to the gate electrode of the first transistor 10, the gate electrode of the second transistor 20, and a gate electrode of the third transistor 30, the first transistor 10 and the second transistor 20 are turned ON, and the third transistor 30 is turned OFF. When a negative bias (a second voltage) Vb2 of the same magnitude is applied to the gate electrode of the first transistor 10, the gate electrode of the second transistor 20, and the gate electrode of the third transistor 30, the first transistor 10 and the second transistor 20 are turned OFF, and the third transistor 30 is turned ON.

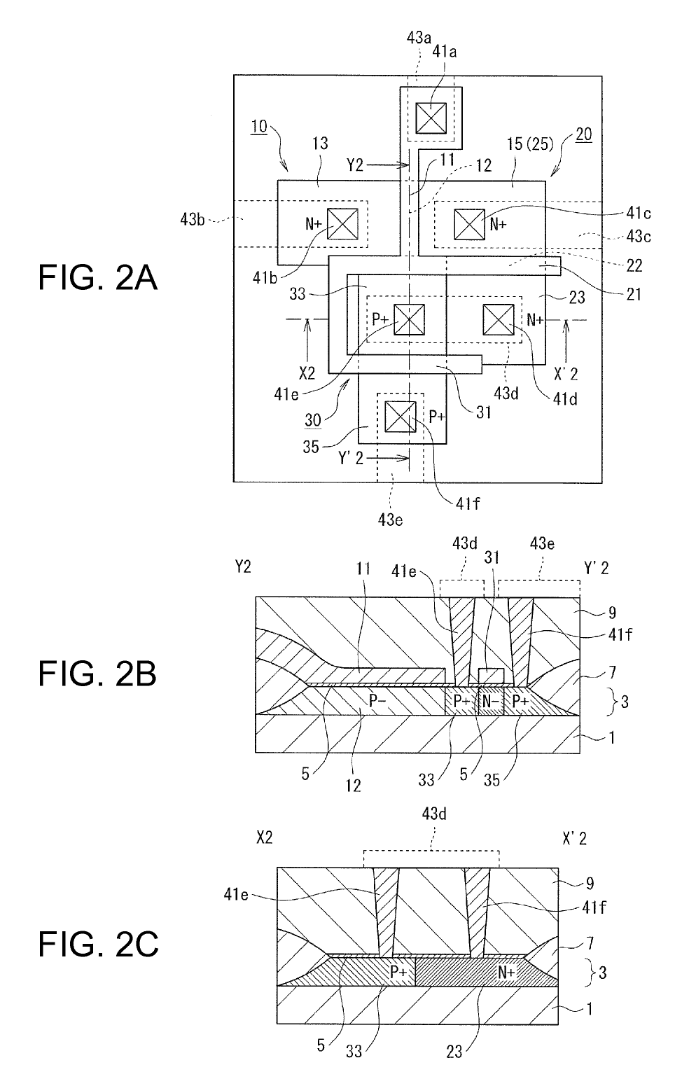

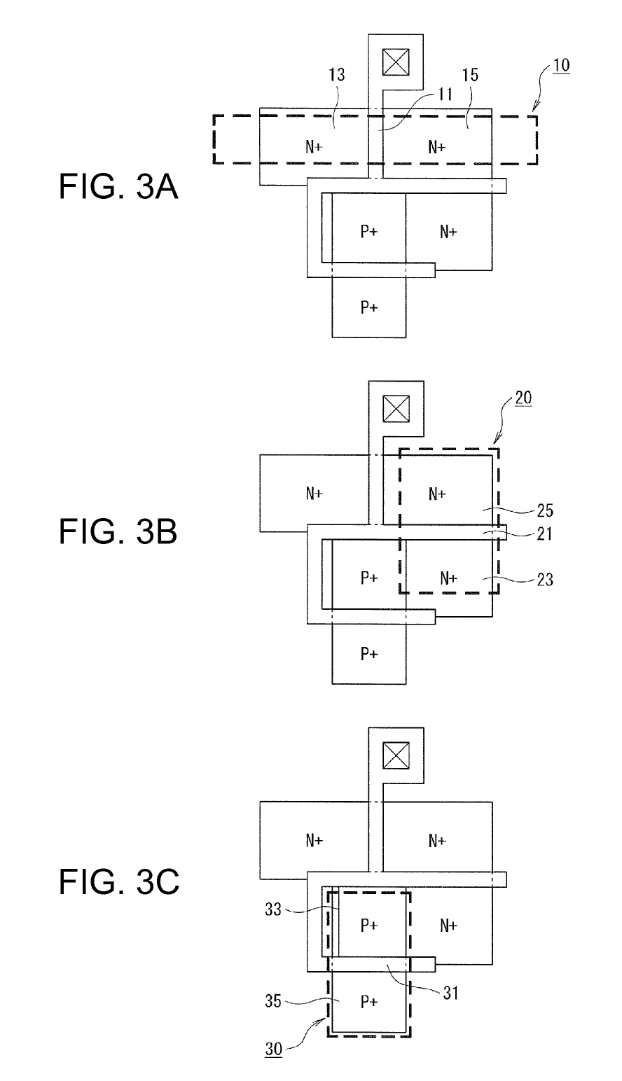

FIGS. 2A to 2C are a plan view and cross-sectional views showing a configuration example of the semiconductor device according to the first embodiment of the invention. FIGS. 3A to 3C are plan views respectively showing arrangement examples of the first transistor 10, the second transistor 20, and the third transistor 30. In FIG. 2A, an inter-layer insulating film is omitted from the illustration for avoiding complication of the drawing.

As shown in FIG. 2A to FIG. 3C, the first transistor 10 has a gate electrode 11 that is formed above an SOI layer 3 on the BOX layer 1 via a gate insulating film 5, and an N-type source 13 and an N-type drain 15 that are formed in the SOI layer 3 below both sides of the gate electrode 11. The second transistor 20 has a gate electrode 21 that is formed above the SOI layer 3 via the gate insulating film 5, and an N-type source 23 and an N-type drain 25 that are formed in the SOI layer 3 below both sides of the gate electrode 21. The third transistor 30 has a gate electrode 31 that is formed above the SOI layer 3 via the gate insulating film 5, and a P-type source 33 and a P-type drain 35 that are formed in the SOI layer 3 below both sides of the gate electrode 31.

The gate insulating film 5 of the first transistor 10, the second transistor 20, and the third transistor 30 is, for example, an oxide film (for example, an SiO₂ film) formed by thermal oxidation of the SOI layer 3, or another insulating film (for example, a high-k film).

As shown in FIGS. 2A to 3C, the periphery of each of the first transistor 10, the second transistor 20, and the third transistor 30 is surrounded by an element isolation layer (for example, an SiO₂ film) 7 formed on the BOX layer 1. In the semiconductor device for example, the gate electrode 11 of the first transistor 10, the gate electrode 21 of the second transistor 20, and the gate electrode 31 of the third transistor 30 are configured with one continuous conductive film (for example, a polysilicon film having conductivity due to an impurity contained therein, or a metal film). On a portion of the conductive film extended over the element isolation layer 7, one contact electrode 41a, for example, is disposed. That is, the gate electrodes 11, 21, and 31 are used in common, and the common contact electrode 41a is disposed for the gate electrodes 11, 21, and 31 used in common. Thus, the number of contact electrodes to be connected to the gate electrodes 11, 21, and 31 can be decreased, and the area of the element can be decreased (compared to the case where the contact electrode is disposed individually for each of the gate electrodes 11, 21, and 31). Moreover, the positive bias Vb1 or the negative bias Vb2 can be applied to the gate electrodes 11, 21, and 31 at the same timing with the same magnitude.

In the semiconductor device, an N-type impurity diffusion layer (that is, an N⁺ layer) formed in the SOI layer 3 is the drain 15 of the first transistor 10 and the drain 25 of the second transistor 20. That is, the drain 15 of the first transistor 10 and the drain 25 of the second transistor 20 are shared through one N⁺ layer. Thus, compared to the case where the drains 15 and 25 are configured with separate impurity diffusion layers, the number of impurity diffusion layers and the number of contact electrodes to be connected to the impurity diffusion layers can be decreased, and therefore the area of the element can be decreased.

In the semiconductor device as shown in FIG. 2B, the source 33 of the third transistor 30 and a first body region 12 of the first transistor 10 are adjacent to each other. In this case, since both the source 33 of the third transistor 30 and the first body region 12 of the first transistor 10 are of P-type for example, the source 33 and the first body region 12 are electrically connected, and the potentials of both of them can be held at substantially the same value (that is, the same potential).

In the semiconductor device as shown in FIG. 2C, the source 23 of the second transistor 20 and the source 33 of the third transistor 30 are adjacent to each other to form a PN junction. A contact electrode 41d formed on the source 23 of the transistor 20 and a contact electrode 41e formed on the source 33 of the third transistor 30 are electrically connected with the wiring 43d formed on an inter-layer insulating film 9. Thus, even when the source 23 of the second transistor 20 is on the high potential side, and the source 33 of the third transistor 30 is on the low potential side (that is, when a reverse bias is applied to the PN junction), current can flow from the source 23 of the second transistor 20 to the source 33 of the third transistor 30 via the contact electrode 41d, the wiring 43d, and the contact electrode 41e.

A second body region 22 that is a region just below the second gate electrode 21 of the second transistor 20 is adjacent to the source 33 of the third transistor 30. In this case, since both the source 33 of the third transistor 30 and the second body region 22 of the second transistor 20 are of P-type for example, the source 33 and the second body region 22 are electrically connected, and both of them can be held at the same potential.

### Characteristics of Transistors

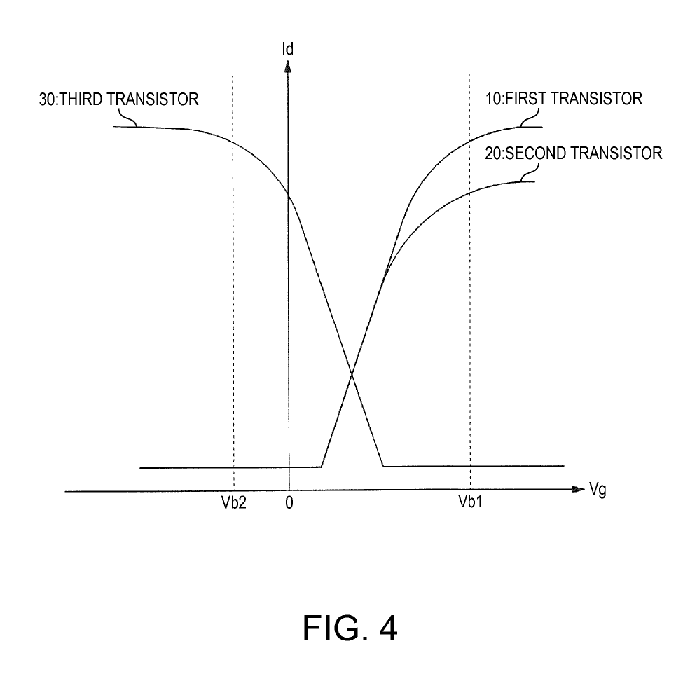

FIG. 4 is a graph schematically showing the transfer characteristics (that is, Vg-Id characteristics) of the first transistor 10, the second transistor 20, and the third transistor 30. In FIG. 4, the horizontal axis represents a gate voltage Vg, while the vertical axis represents a drain current Id.

As shown in FIG. 4, in the N-channel first transistor 10 and the N-channel second transistor 20, when the gate voltage Vg is changed in a direction from 0[V] to a positive potential for example, under the condition where a drain voltage Vd is constant, the drain current Id is also increased in response to the change. In the P-channel third transistor 30, on the other hand, when the gate voltage Vg is changed in the direction from 0[V] to a positive potential under the condition where the drain voltage Vd is constant, the drain current Id is decreased in response to the change.

In FIG. 4 for example, the first transistor 10 and the second transistor 20 are set to the enhancement type, while the third transistor 30 is set to the depletion type. A threshold voltage Vth1 of the first transistor 10, a threshold voltage Vth2 of the second transistor 20, and a threshold voltage Vth3 of the third transistor 30 are adjusted so that when the gate voltage Vg is the positive bias Vb1, the first transistor 10 and the second transistor 20 are turned ON, and the third transistor 30 is turned OFF, while when the gate voltage is the negative bias Vb2 (in this case, the negative bias Vb2 includes a zero bias (that is, Vg=0)), the first transistor 10 and the second transistor 20 are turned OFF, and the third transistor 30 is turned ON.

That is, the magnitude relationship between the biases Vb1 and Vb2 and the threshold voltages Vth1, Vth2, and Vth3 is exemplified as follows: the positive bias Vb1 has a greater value than the threshold voltages Vth1 and Vth2 or the same value as the threshold voltages Vth1 and Vth2 (that is, Vb1≧Vth1, Vb1≧Vth2); and the absolute value of the negative bias Vb2 is greater than the absolute value of the threshold voltage Vth3 or the same as the absolute value of the threshold voltage Vth3 (that is, |Vb2|≧|Vth3|).

FIG. 4 shows the case where the first transistor 10 and the second transistor 20 are of the enhancement type, and the third transistor 30 is of the depletion type. However, the invention is not limited to this case. Depending on other characteristics of the device, the first transistor 10 and the second transistor 20 may be of the depletion type, and the third transistor 30 may be of the enhancement type. Alternatively, all the first transistor 10, the second transistor 20, and the third transistor 30 may be of the enhancement type, and all of them may be of the depletion type. When the threshold voltage Vth2 of the second transistor is set lower than the threshold voltage Vth1 of the first transistor, a higher effect can be provided. However, they may be the same threshold voltage.

### Increase in ON Current

In the semiconductor device, when the first transistor 10 is ON, the second transistor 20 is turned ON, and the third transistor 30 is turned OFF. Thus, the first body region 12 can be electrically disconnected from, for example, VSS (or GND), and therefore the first transistor 10 can be made into a body bias structure (that is, a bias can be given to the body potential). Moreover, part of an ON current that should flow from the drain 15 to the source 13 of the first transistor 10 can flow into the first body region 12 of the first transistor 10 and the second body region 22 of the second transistor 20 through a channel of the second transistor 20.

Due to the flowing current in this case, the potential of the first body region 12 and the potential of the second body region 22 increase, and the threshold voltage Vth1 of the first transistor 10 and the threshold voltage Vth2 of the second transistor 20 decrease. As a result, the ON current increases in both the first transistor 10 and the second transistor 20. Such a decrease in the threshold voltages Vth1 and Vth2 and an increase in the ON current in response to the decrease cease when there is no difference between the amount of charge flowing into the first body region 12 through the second transistor 20 and the amount of charge flowing out of the first body region 12 into the source 13 (that is, when they are balanced). At the point of time when the decrease in the threshold voltages Vth1 and Vth2 and the increase in the ON current have ceased in this manner, the potential of the first body region 12 and the potential of the second body region 22 are stabilized.

According to the semiconductor device as described above, when the first transistor 10 is ON, the ON current of the first transistor 10 can be increased due to the effect of body bias. Not only merely the effect of body bias but also the part of the ON current is used to increase the potential of the first body region 12 and the potential of the second body region 22, and therefore the threshold voltage Vth1 of the first transistor 10 and the threshold voltage Vth2 of the second transistor 20 can be decreased. Accordingly, compared to the case of merely depending only on the effect of body bias, the ON current of the first transistor 10 can be increased without waste.

### Decrease in OFF Current

On the other hand, when the first transistor 10 is OFF, the second transistor 20 is turned OFF, and the third transistor 30 is turned ON. Therefore, the first transistor 10 can be made into a body contact structure (that is, the body potential can be fixed). When the first transistor 10 is OFF, the potential of the first body region 12 of the first transistor 10 is reset due to the effect of body contact. Therefore, the history effect in the first transistor 10 is suppressed, and an OFF current of the first transistor 10 can be decreased.

The reason why the OFF current is decreased will be described further in detail. In a MISFET, impact ionization occurs (this is not a phenomenon inherent to SOI) under such a condition as: the drain voltage Vd>about 1.1 V. Here, the impact ionization is a phenomenon in which numerous electron-hole pairs are generated due to the collision of charged particles and Si atoms. That is, in the case where charged particles (electrons in the case of an N-channel MISFET, and holes in the case of a P-channel MISFET) flowing through a channel when the channel is ON are accelerated by an electric field near a drain and collide with Si atoms with an energy of a certain level or higher (about 1.5 eV or higher), Si atoms are ionized due to the energy and release electrons. Along with the release of electrons, holes are also generated. That is, numerous electron-hole pairs are generated due to the impact ionization.

In the case of an N-channel MISFET, the generated electrons flow to a drain at a high potential, while holes flow into a body region at a low potential (the flows of electrons and holes are reversed in the case of a P-channel MISFET). In the case of the N-channel MISFET, the body potential is increased due to the supply of holes. In the case of the P-channel MISFET, the body potential is decreased due to the supply of electrons. In either case, a threshold voltage Vth of the MISFET is decreased due to the impact ion. Further, carriers themselves are also increased in number, leading to an increase in the ON current. In the case of SOI, since the potential of the body region floats, the influence is obviously large compared to the case of bulk.

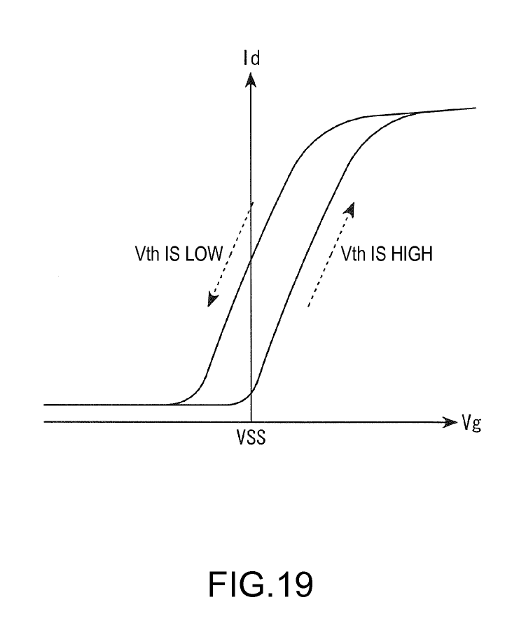

FIG. 19 schematically shows a change in Vth due to impact ionization in the case of an N-channel PD-SOI MISFET. The horizontal axis of FIG. 19 represents the gate voltage Vg, while the vertical axis thereof represents the drain current Id. When a channel current (that is, the ON current) flows, Vth is decreased due to impact ionization. Accordingly, as shown in FIG. 19, since Vth is already decreased when the PD-SOI MISFET is changed from ON to OFF, a channel current when OFF (that is, the OFF current) is increased. In the invention, on the other hand, when the PD-SOI MISFET (that is, the first transistor 10) is OFF, there is a path (that is, the third transistor 30) for discharging holes accumulated in the body region, and therefore the decrease in Vth can be prevented, and the OFF current can be suppressed low.

### Method for Manufacturing Semiconductor Device

Next, a method for manufacturing the semiconductor device will be described.

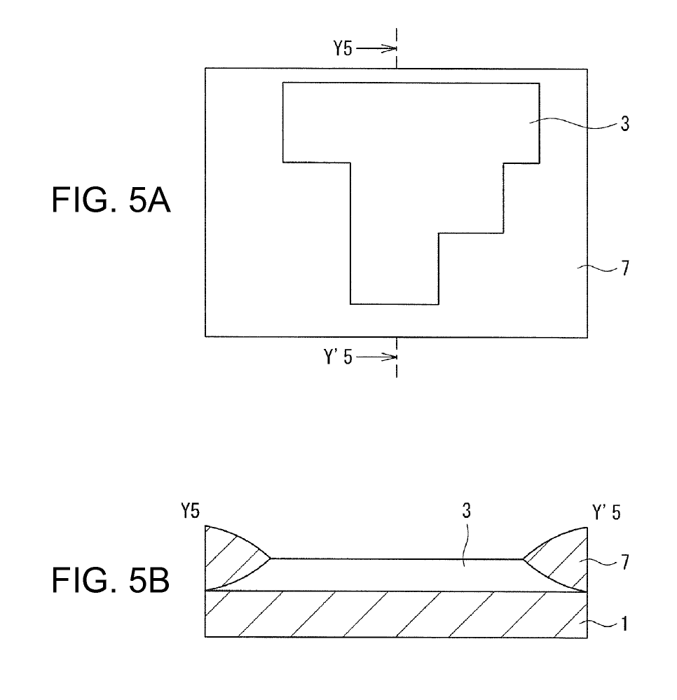

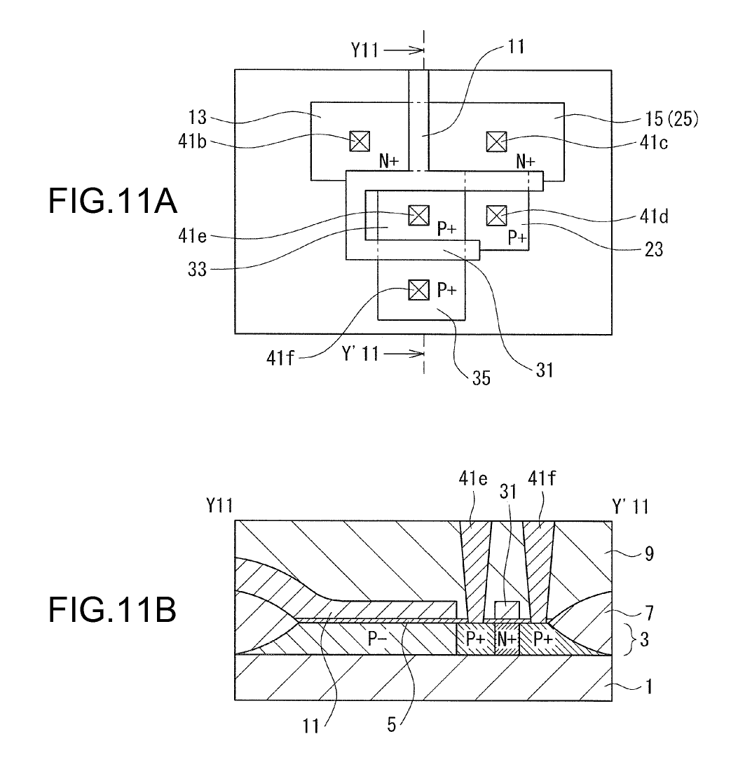

FIGS. 5A to 11B are flow sheets showing the method for manufacturing the semiconductor device according to the first embodiment of the invention. In FIG. 11A, the inter-layer insulating film is omitted from the illustration for avoiding complication of the drawing.

In FIGS. 5A and 5B, an SOI substrate in which the BOX layer 1 is formed on a supporting substrate (not shown) and the SOI layer 3 is formed on the BOX layer 1 is first prepared. The SOI substrate is formed by, for example, the separation by implanted oxygen (SIMOX) process or the bonding process. Next, the element isolation layer 7 is formed in the SOI layer 3 using, for example, the local oxidation of silicon (LOCOS) process. A region surrounded by the element isolation layer 7 in plan view serves as an element region.

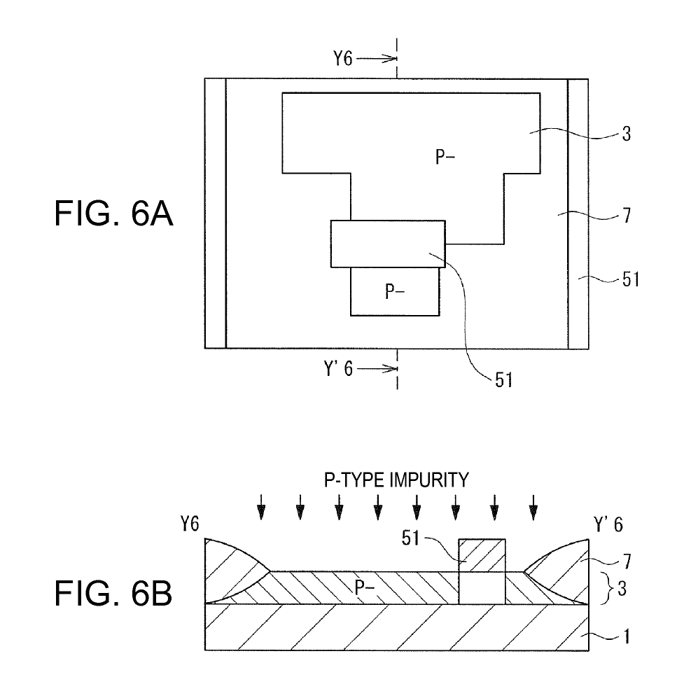

Next, as shown in FIGS. 6A and 6B, a resist pattern 51 having a shape that covers a region of the element region serving as a channel of the third transistor 30 and exposes the other regions is formed on the SOI substrate. The formation of the resist pattern 51 is performed using, for example, a photolithography technique. Using the resist pattern 51 as a mask, a P-type impurity such as boron, for example, is ion implanted into the SOI layer 3. Thus, a P-type impurity layer (that is, a P⁻ layer) is formed in the SOI layer 3. After forming the P⁻ layer, the resist pattern 51 is removed from over the SOI layer 3.

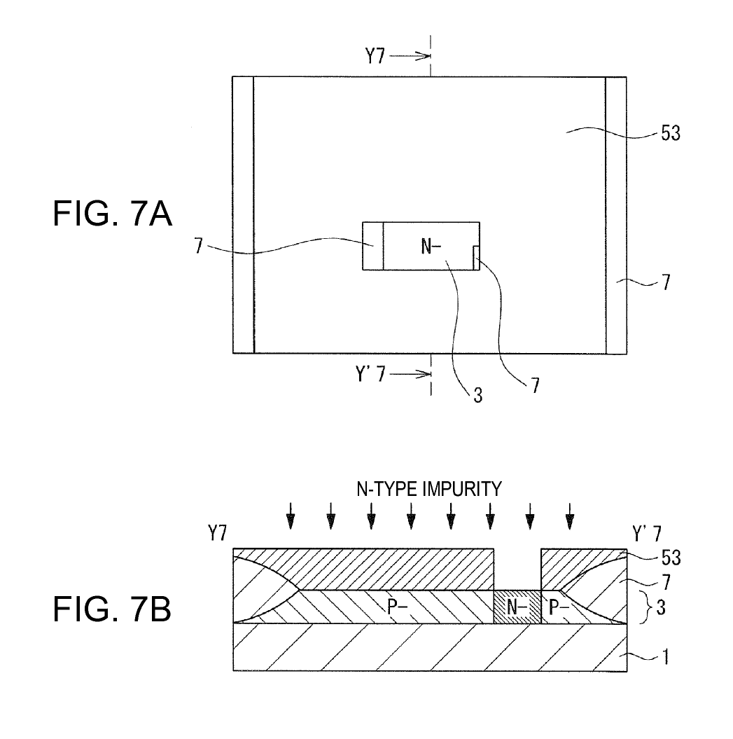

Next, as shown in FIGS. 7A and 7B, a resist pattern 53 having a shape that exposes the region of the element region serving as the channel of the third transistor 30 and covers the other regions is formed on the SOI substrate. Using the resist pattern 53 as a mask, an N-type impurity such as phosphorus or arsenic, for example, is ion implanted into the SOI layer 3. Thus, an N-type impurity layer (that is, an N⁻ layer) is formed in the SOI layer 3. After forming the N⁻ layer, the resist pattern 53 is removed from over the SOI layer 3.

The step of forming the N⁻ layer shown in FIGS. 7A and 7B may be performed before the step of forming the P⁻ layer shown in FIGS. 6A and 6B. That is, either the step of forming the N⁻ layer or the step of forming the P⁻ layer can be performed first.

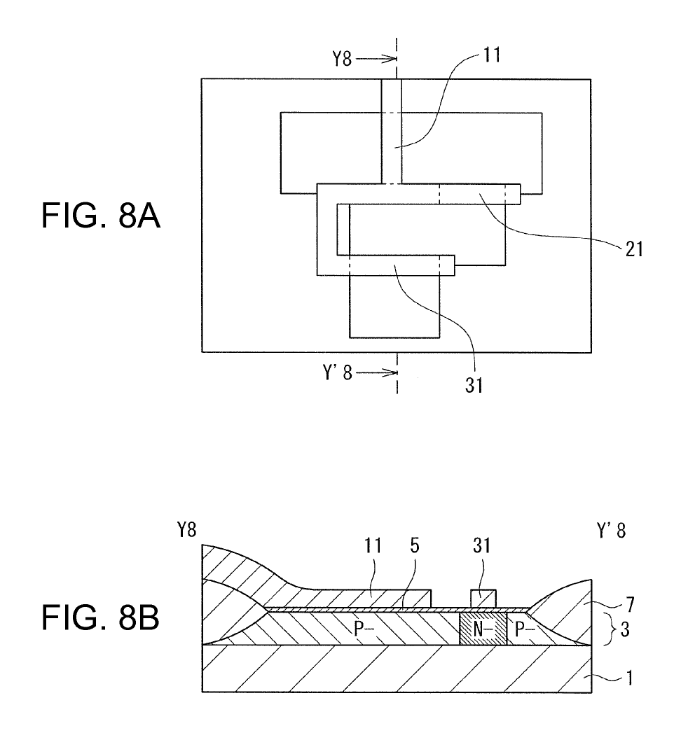

Next, as shown in FIGS. 8A and 8B, the SOI layer 3 is subjected to thermal oxidation, for example, to form the gate insulating film 5 on the surface thereof. A conductive film (for example, a polysilicon film or a metal film) serving as the material of the gate electrode is formed on the gate insulating film 5, and the conductive film is patterned to form the gate electrodes 11, 21, and 31.

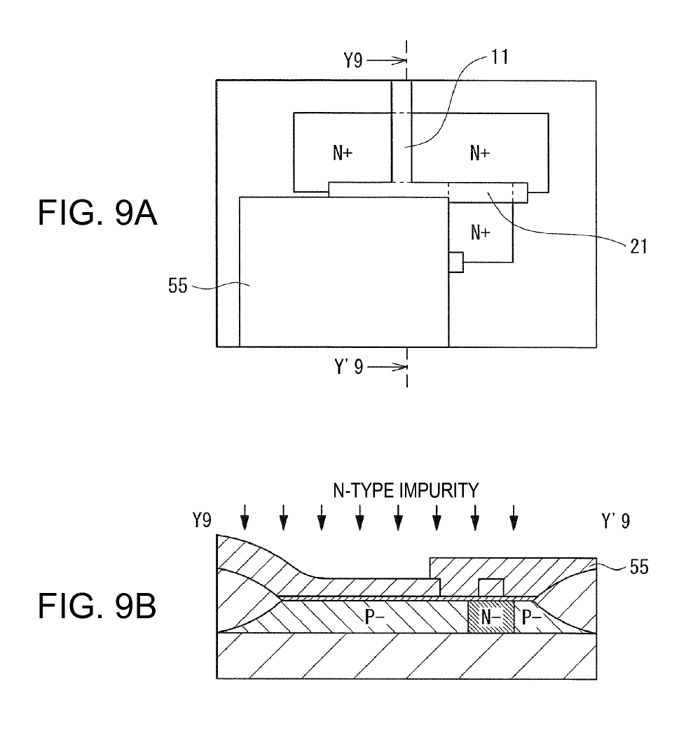

Next, as shown in FIGS. 9A and 9B, a resist pattern 55 having a shape that covers a region of the element region where the third transistor 30 is formed and exposes the other regions is formed on the SOI substrate. Using the resist pattern 55 and the conductive film constituting the gate electrodes 11, 21, and 31 as masks, an N-type impurity such as phosphorus or arsenic, for example, is ion implanted into the SOI layer 3. Thus, an N-type impurity layer (that is, an N⁺ layer) is formed in the SOI layer 3. After forming the N⁺ layer, the resist pattern 55 is removed from over the SOI layer 3.

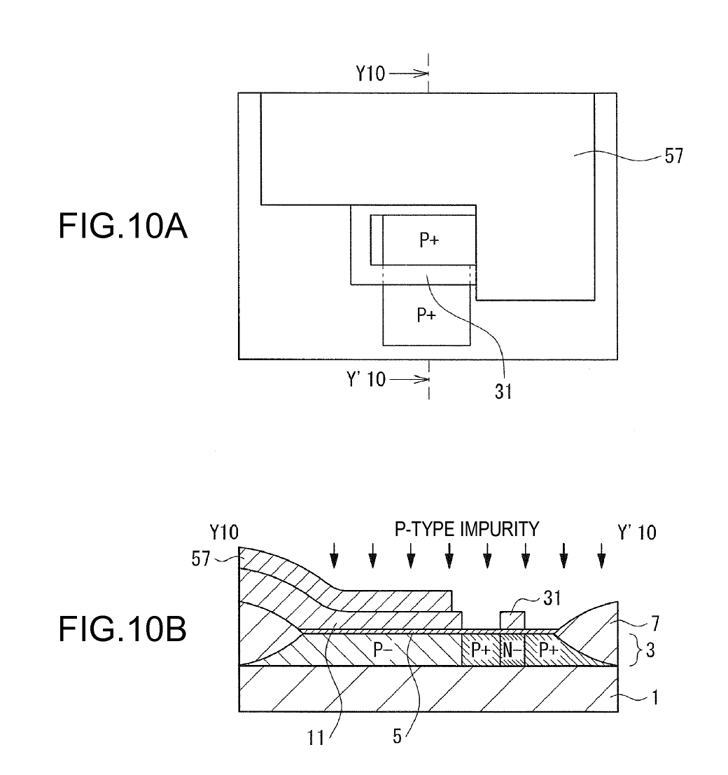

Next, as shown in FIGS. 10A and 10B, a resist pattern 57 having a shape that exposes the region of the element region where the third transistor 30 is formed and covers the other regions is formed on the SOI substrate. Using the resist pattern 57 and the conductive film constituting the gate electrodes 11, 21, and 31 as masks, a P-type impurity such as boron, for example, is ion implanted into the SOI layer 3. Thus, a P-type impurity layer (that is, a P⁺ layer) is formed in the SOI layer 3. After forming the P⁺ layer, the resist pattern 57 is removed from over the SOI layer 3. Thereafter, the SOI substrate is subjected to a thermal treatment, whereby the P-type impurity and the N-type impurity introduced into the SOI layer 3 are diffused (that is, activated).

The step of forming the P⁺ layer shown in FIGS. 10A and 10B may be performed before the step of forming the N⁺ layer shown in FIGS. 9A and 9B. That is, either the step of forming the N⁺ layer or the step of forming the P⁺ layer can be performed first.

Next, as shown in FIG. 11B, the inter-layer insulating film 9 is deposited on the SOI substrate. Further, openings are formed on the N⁺ layer, the P⁺ layer, and the portion of the gate electrodes 11, 21, and 31 extended over the element isolation layer 7.

A conductive member such as tungsten, for example, is buried into the openings to form contact electrodes 41a to 41f as shown in FIGS. 11A and 11B (as for the contact electrode 41a, refer to FIG. 2A). That is, as shown in FIG. 2A, the contact electrode 41a is formed on the portion, which is extended over the element isolation layer 7, of the conductive film constituting the gates 11, 21, and 31. The contact electrode 41b is formed on the N⁺ layer as the source 13 of the first transistor 10. The contact electrode 41c is formed on the N⁺ layer as the drain 15 of the first transistor 10 and also as the drain 25 of the second transistor 20. The contact electrode 41d is formed on the N⁺ layer as the source 23 of the second transistor 20; the contact electrode 41e is formed on the P⁺ layer as the source 33 of the third transistor 30; and the contact electrode 41f is formed on the P⁺ layer as the drain 35 of the third transistor 30.

The wirings 43a to 43e (for example, refer to FIGS. 2A to 2C) are formed on the contact electrodes 41a to 41f. That is, the wiring 43a is formed on the contact electrode 41a; the wiring 43b is formed on the contact electrode 41b; the wiring 43c is formed on the contact electrode 41c; the wiring 43d is formed on the contact electrode 41d and the contact electrode 41e continuously from the contact electrode 41d to the contact electrode 41e; and the wiring 43e is formed on the contact electrode 41f. Thus, the semiconductor device shown in, for example, FIGS. 2A to 2C is completed.

According to the semiconductor device according to the first embodiment of the invention as described above, in accordance with the ON and OFF of the first transistor 10, the body bias structure and the body contact structure can be switched, and the threshold voltages Vth1 and Vth2 can be decreased using the part of the ON current when the first transistor 10 is ON. Therefore, compared to a partially depleted semiconductor device in the related art, an extremely high ON/OFF ratio and stable operation can be realized simultaneously.

### 2 Second Embodiment

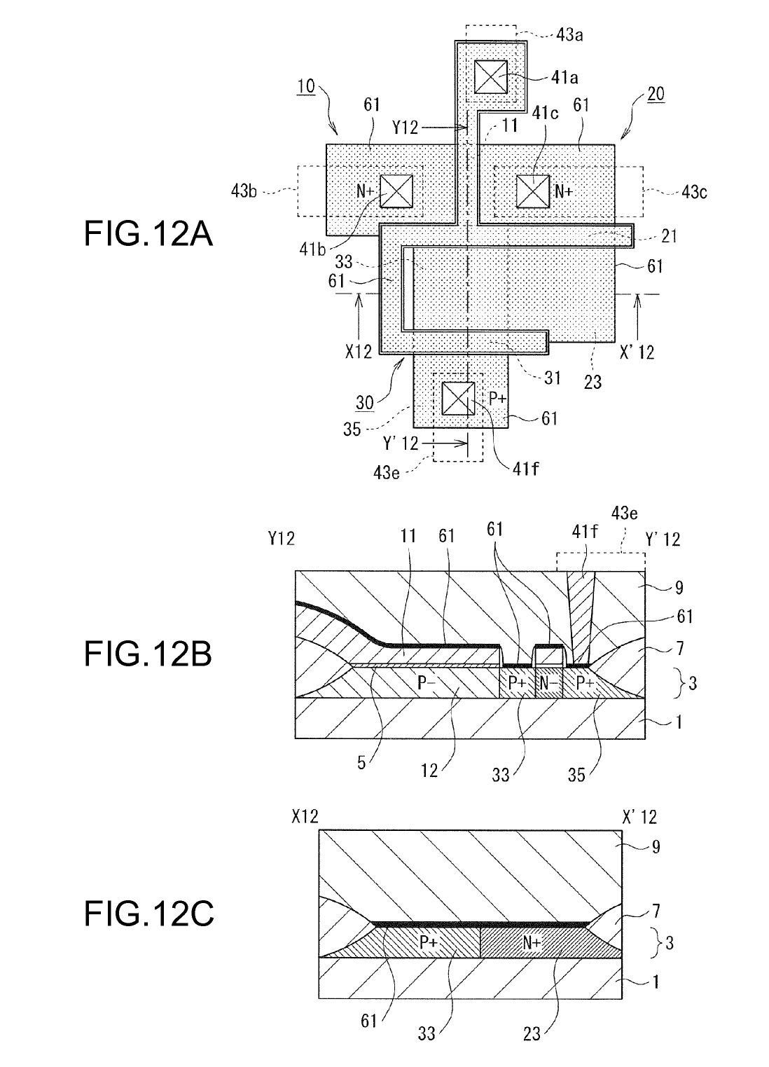

In the first embodiment, the case where the N⁺ layer as the source 23 of the second transistor 20 and the P⁺ layer as the source 33 of the third transistor 30 are electrically connected via the contact electrodes 41d and 41e and the wiring 43d has been described. In the invention, however, the connection method between the N⁺ layer and the P⁺ layer is not limited to this case. As shown in FIGS. 12A to 12C for example, a silicide (that is, a compound layer of silicon and metal) 61 is formed on the N⁺ layer as the source 23 and the P⁺ layer as the source 33 continuously from the N⁺ layer and the P⁺ layer, and the N⁺ layer and the P⁺ layer may be electrically connected with the silicide 61. As the silicide 61 for example, titanium silicide (TiSix), nickel silicide (NiSix), tungsten silicide (WSix), or the like can be used.

Even with this configuration, the part of the ON current that should flow through the channel of the first transistor 10 can flow into the first body region 12 of the first transistor 10 and the second body region 22 of the second transistor 20 through the silicide 61. Therefore, the same effect as that of the first embodiment can be provided.

For example, the silicide 61 may be formed as follows: a metal film is deposited on the SOI substrate formed with a side wall 63; the SOI substrate is subjected to an annealing treatment (first time) to react the metal film with silicon (the surface of the SOI layer 3 and the surface of the gate electrode); an unreacted metal film is removed from over the SOI substrate; and thereafter, the SOI substrate is subjected to an annealing treatment (second time) at a temperature higher than that of the first time to stabilize the silicide. Thus, the silicide 61 is formed not only on the N⁺ layer and the P⁺ layer as the source and drain of each of the transistors but also on the gate electrodes 11, 21, and 31.

As shown in FIG. 12A, since the silicide 61 is formed continuously on the gate electrodes 11, 21, and 31, even when, for example, the gate electrodes 11 and 21 are formed of a silicon film containing an N-type impurity; the gate electrode 31 is formed of a silicon film containing a P-type impurity; and therefore, a PN junction is produced between the gate electrodes 11 and 21 and the gate electrode 31, the gate electrodes 11 and 21 and the gate electrode 31 can be electrically connected via the silicide 61.

### 3 Third Embodiment

In the first and second embodiments, as for the positional relationship among the transistors within the semiconductor device as shown in FIGS. 3A and 3C for example, the case where the gate length direction (that is, a direction of a straight line connecting the source and drain) of the first transistor 10 is perpendicular to the gate length direction of the third transistor 30 in plan view has been shown. In the semiconductor device, however, the positional relationship among the transistors is not limited to this case.

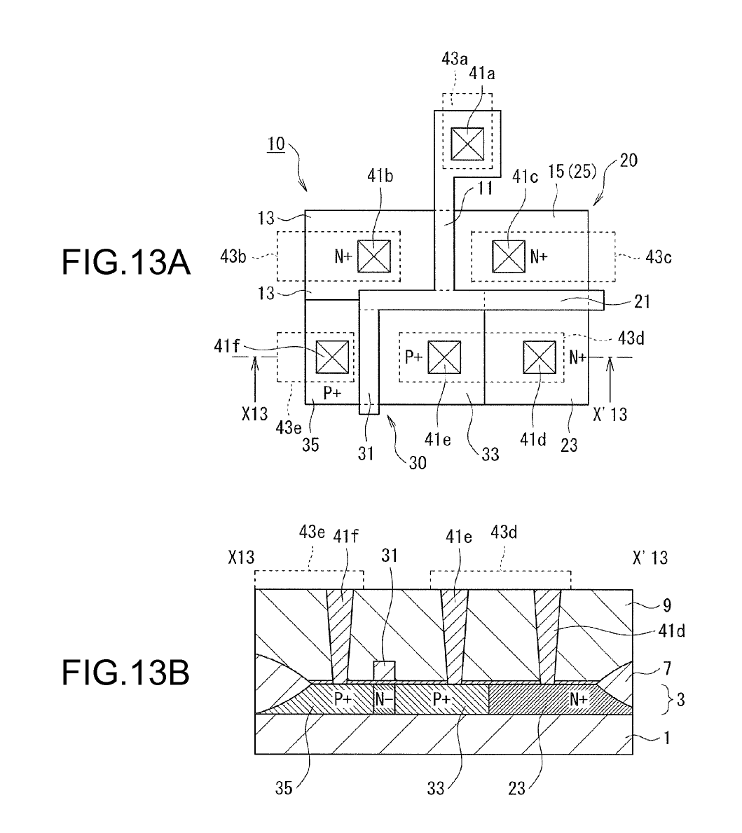

As shown in FIGS. 13A and 13B for example, the transistors may be arranged so that the gate length direction of the first transistor 10 is parallel to the gate length direction of the third transistor 30 in plan view. Even with this configuration, the same effect as that of the first and second embodiments can be provided. Depending on the arrangement of other elements and the like that are not shown, space saving is possible, which provides a possibility that can decrease the area of the semiconductor device.

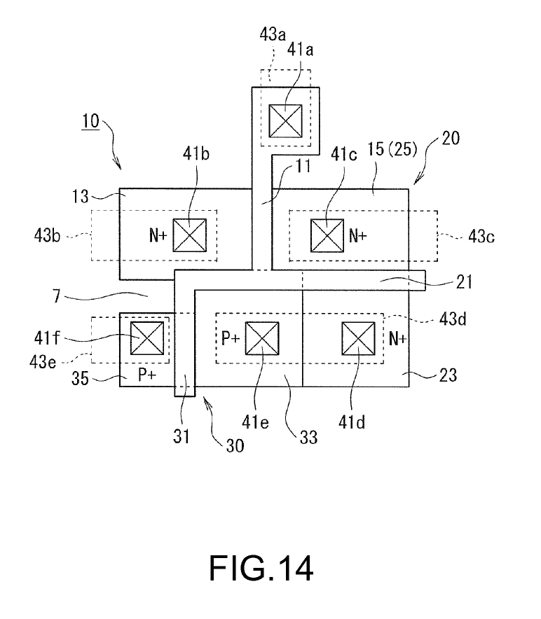

Further as shown in FIG. 14, when the transistors are arranged so that the gate length direction of the first transistor 10 is parallel to the gate length direction of the third transistor 30 in plan view, the source 13 of the first transistor 10 and the drain 35 of the third transistor 30 may be electrically isolated (that is, the element isolation layer 7 may be interposed therebetween). With this configuration, a parasitic capacitance of the source 13 of the first transistor 10 can be decreased, which can further contribute to an increase in ON current in the first transistor 10.

### 4 Fourth Embodiment

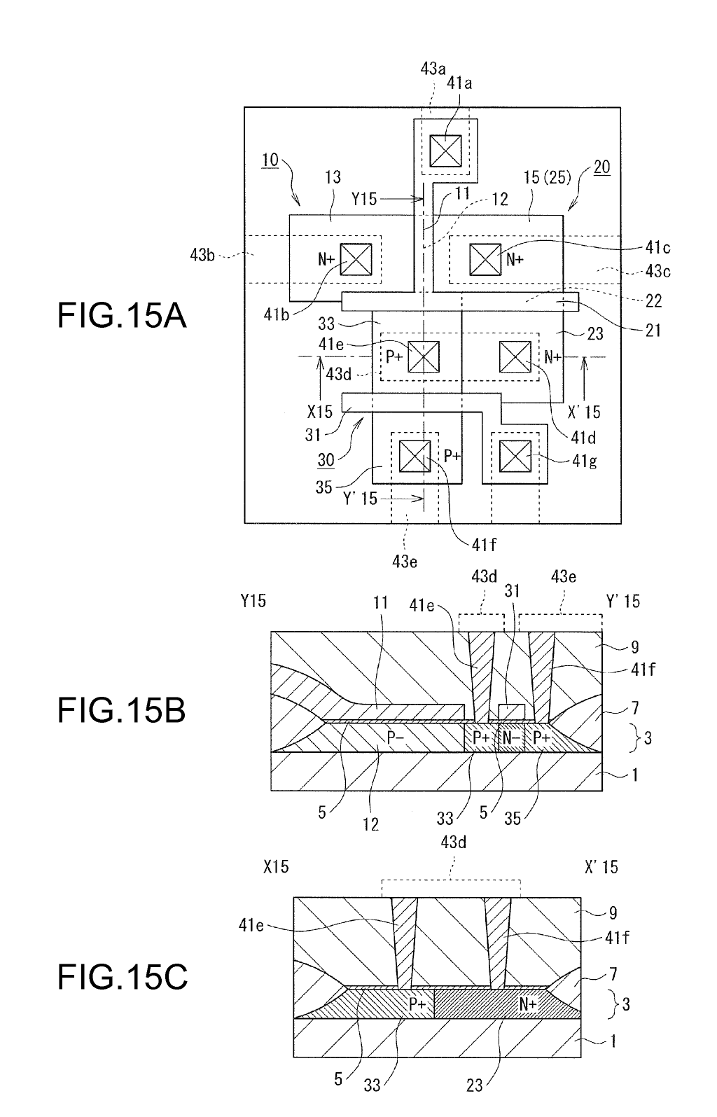

In the first to third embodiments, the case where the gate electrodes 11, 21, and 31 are configured with one continuous conductive film has been described. However, the invention is not limited to this case. As shown in FIG. 15A to 15C for example, a conductive film constituting the gate electrodes 11 and 21 and a conductive film constituting the gate electrode 31 may be separated from each other. Further, a contact electrode 41g may be disposed for the gate electrode 31.

Even with this configuration, by applying a positive bias to the contact electrodes 41a and 41g at the same timing, the first transistor 10 and the second transistor 20 can be turned ON, and the third transistor 30 can be turned OFF. By applying a negative bias to the contact electrodes 41a and 41g at the same timing, the first transistor 10 and the second transistor 20 can be turned OFF, and the third transistor 30 can be turned ON. Accordingly, in the same manner as in the first to third embodiments, an extremely high ON/OFF ratio and stable operation can be realized simultaneously.

In the first to fourth embodiments, the N⁺ layer as the drain 15 of the first transistor 10 and also as the drain 25 of the second transistor 20 corresponds to a “first impurity diffusion layer” of the invention, and the N⁺ layer as the source 13 of the first transistor 10 corresponds to a “second impurity diffusion layer” of the invention. The P⁺ layer as the drain 35 of the third transistor 30 corresponds to a “third impurity diffusion layer” of the invention, and the N⁺ layer as the source 23 of the second transistor 20 corresponds to a “fourth impurity diffusion layer” of the invention. The P⁺ layer as the source 33 of the third transistor 30 corresponds to a “fifth impurity diffusion layer” of the invention.

### 5 Fifth Embodiment

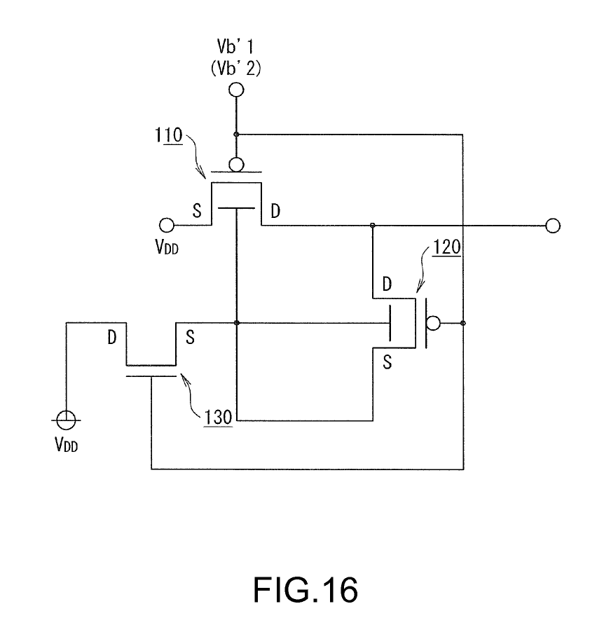

In the first to fourth embodiments, the case where a “first conductivity type” of the invention is N-type and a “second conductivity type” thereof is P-type has been described. However, the invention is not limited to this case. The “first conductivity type” may be P-type, and the “second conductivity type” may be N-type. That is, a configuration shown in FIG. 16 may also be employed.

FIG. 16 is a circuit diagram showing a configuration example of a semiconductor device according to a fifth embodiment of the invention. As shown in FIG. 16, the semiconductor device is configured to include a P-channel first transistor 110, a P-channel second transistor 120, and an N-channel third transistor 130. Each of the first transistor 110, the second transistor 120, and the third transistor 130 is a partially depleted MIS transistor formed in an SOI layer on a BOX layer.

In FIG. 16, the connection relationship among the first transistor 110, the second transistor 120, and the third transistor 130 will be described. A drain (D) of the first transistor 110 and a drain of the second transistor 120 are electrically connected. A source (S) of the second transistor 120, a region (that is, a first body region) of the SOI layer just below a gate electrode of the first transistor 110, a region (that is, a second body region) of the SOI layer just below a gate electrode of the second transistor 120, and a source of the third transistor 130 are electrically connected to one another. A source of the first transistor 110 is connected to a first constant-potential power supply line (for example, VDD), and the source of the third transistor 130 is connected to a second constant-potential power supply line (for example, VDD). VDD is a constant potential.

In the semiconductor device for example, when a negative bias (the first voltage) Vb′1 of the same magnitude is applied to the gate electrode of the first transistor 110, the gate electrode of the second transistor 120, and a gate electrode of the third transistor 130, the first transistor 110 and the second transistor 120 are turned ON, and the third transistor 130 is turned OFF. When a positive bias (the second voltage) Vb′2 of the same magnitude is applied to the gate electrode of the first transistor 110, the gate electrode of the second transistor 120, and the gate electrode of the third transistor 130, the first transistor 110 and the second transistor 120 are turned OFF, and the third transistor 130 is turned ON.

In the fifth embodiment, the P-channel first transistor 110 and the P-channel second transistor 120 can be set to the enhancement type, and the N-channel third transistor 130 can be set to the depletion type. In that case, the positive bias Vb′2 includes a zero bias (that is, Vg=0).

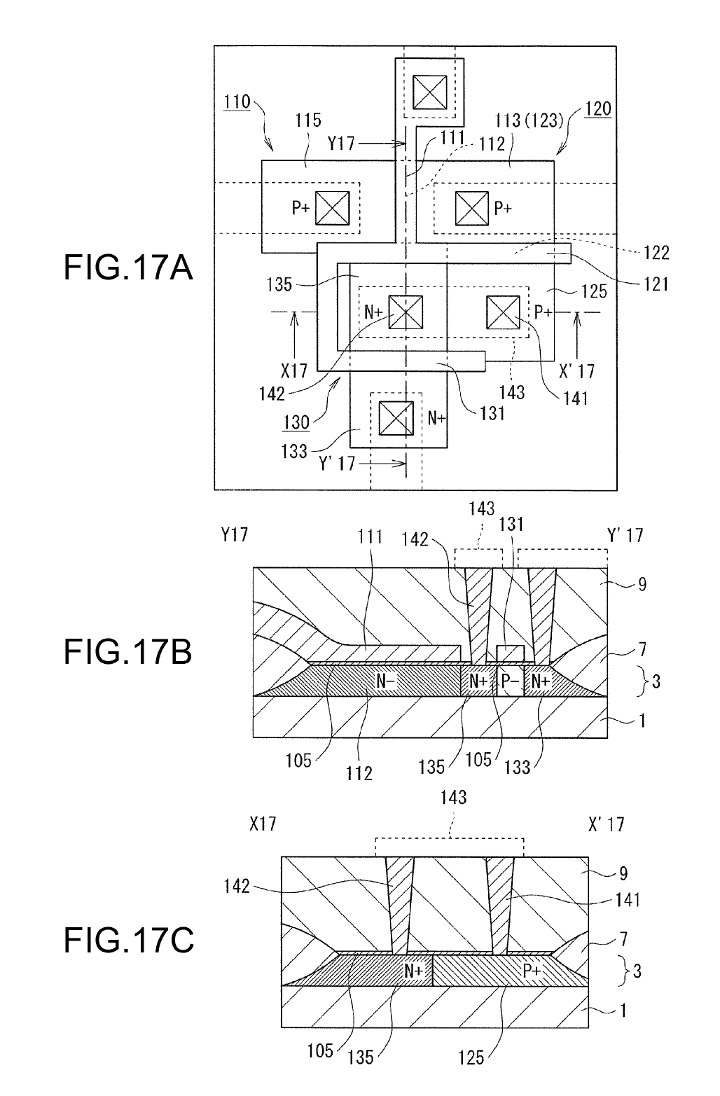

FIGS. 17A to 17C are a plan view and cross-sectional views showing a configuration example of the semiconductor device according to the fifth embodiment of the invention. In FIG. 16A, the inter-layer insulating film is omitted from the illustration for avoiding complication of the drawing.

As shown in FIGS. 17A to 17C, the first transistor 110 has a gate electrode 111 that is formed above the SOI layer 3 on the BOX layer 1 via a gate insulating film 105, and a P-type source 113 and a P-type drain 115 that are formed in the SOI layer 3 below both sides of the gate electrode 111. The second transistor 120 has a gate electrode 121 that is formed above the SOI layer 3 via the gate insulating film 105, and a P-type source 123 and a P-type drain 125 that are formed in the SOI layer 3 below both sides of the gate electrode 121. The third transistor 130 has a gate electrode 131 that is formed above the SOI layer 3 via the gate insulating film 105, and an N-type source 133 and an N-type drain 135 that are formed in the SOI layer 3 below both sides of the gate electrode 131.

In the semiconductor device as shown in FIG. 17A, the source 113 of the first transistor 110 and the source 123 of the second transistor 120 are shared through one P⁺ layer formed in the SOI layer.

In the semiconductor device as shown in FIG. 17B, the drain 135 of the third transistor 130 and a first body region 112 of the first transistor 110 are adjacent to each other. In this case, since both the drain 135 of the third transistor 130 and the first body region 112 of the first transistor 110 are of N-type for example, the drain 135 and the first body region 112 are electrically connected, and the potentials of both of them can be held at substantially the same value (that is, the same potential).

A second body region 122 that is a region just below the gate electrode 121 of the second transistor 120 is adjacent to the drain 135 of the third transistor 130. In this case, both the drain 135 of the third transistor 130 and the second body region 122 of the second transistor 120 are of N-type for example, the drain 135 and the second body region 122 are electrically connected, and both of them can be held at the same potential.

In the semiconductor device as shown in FIG. 17C, the drain 125 of the second transistor 120 and the drain 135 of the third transistor 130 are adjacent to each other to form a PN junction. A contact electrode 141 formed on the drain 125 of the second transistor 120 and a contact electrode 142 formed on the drain 135 of the third transistor 130 are electrically connected with a wiring 143 formed on the inter-layer insulating film 9.

Even with this configuration, when the first transistor 110 is ON, the second transistor 120 is turned ON, and the third transistor 130 is turned OFF. Therefore, the first transistor 110 can be made into the body bias structure. When the first transistor 110 is OFF, the second transistor 120 is turned OFF, and the third transistor 130 is turned ON. Therefore, the first transistor 110 can be made into the body contact structure.

Further, when the first transistor 110 is ON, part of the ON current that should flow from the source 113 to the drain 115 of the first transistor 110 can flow out of the first body region 112 of the first transistor 110 and the second body region 122 of the second transistor 120 through a channel of the second transistor 120. Thus, the potential of the first body region 112 and the potential of the second body region 122 can be decreased; the absolute value |Vth1| of the threshold voltage of the first transistor 110 and the absolute value |Vth2| of the threshold voltage of the second transistor 120 can be decreased; and the ON current of the first transistor 110 can be increased.

Accordingly, even with the configuration shown in FIGS. 17A to 17C, an extremely high ON/OFF ratio and stable operation can be realized simultaneously in the same manner as the semiconductor devices described in the first to third embodiments.

In the fifth embodiment, the P⁺ layer as the source 113 of the first transistor 110 and also as the source 123 of the second transistor 120 corresponds to the “first impurity diffusion layer” of the invention, and the P⁺ layer as the drain 115 of the first transistor 110 corresponds to the “second impurity diffusion layer” of the invention. The N⁺ layer as the source 133 of the third transistor 130 corresponds to the “third impurity diffusion layer” of the invention, and the P⁺ layer as the drain 125 of the second transistor 120 corresponds to the “fourth impurity diffusion layer” of the invention. The N⁺ layer as the drain 135 of the third transistor 130 corresponds to the “fifth impurity diffusion layer” of the invention.

The entire disclosure of Japanese Patent Application No. 2009-260838, filed Nov. 16, 2009 is expressly incorporated by reference herein.

What is claimed is:

1. A semiconductor device comprising:
a partially depleted first transistor formed in a semiconductor layer on an insulating layer;
a second transistor formed in the semiconductor layer; and
a third transistor formed in the semiconductor layer, wherein
the first transistor has
a first gate electrode formed above the semiconductor layer via an insulating film and
a first source or a first drain of a first conductivity type formed in the semiconductor layer below a side of the first gate electrode,
the second transistor has
a second gate electrode formed above the semiconductor layer via the insulating film and
a second source or a second drain of the first conductivity type formed in the semiconductor layer below a side of the second gate electrode,
the third transistor has
a third gate electrode formed above the semiconductor layer via the insulating film and
a third source or a third drain of a second conductivity type formed in the semiconductor layer below a side of the third gate electrode,
one of the first source and the first drain and one of the second source and the second drain are electrically connected, and
the other of the second source and the second drain, a region of the semiconductor layer just below the first gate electrode, and one of the third source and the third drain are electrically connected to one another.

2. The semiconductor device according to claim 1, wherein when a first voltage is applied to the first gate electrode, the second gate electrode, and the third gate electrode, the first transistor and the second transistor are turned on, and the third transistor is turned off,
while when a second voltage is applied to the first gate electrode, the second gate electrode, and the third gate electrode, the first transistor and the second transistor are turned off, and the third transistor is turned on.

3. The semiconductor device according to claim 1, wherein the second transistor is a partially depleted transistor.

4. The semiconductor device according to claim 3, wherein a region of the semiconductor layer just below the second gate electrode is electrically connected to the other of the second source and the second drain.

5. The semiconductor device according to claim 1, wherein the first gate electrode, the second gate electrode, and the third gate electrode are electrically connected to one another.

6. The semiconductor device according to claim 3, further comprising a first impurity diffusion layer of the first conductivity type formed in the semiconductor layer, wherein
the first impurity diffusion layer is one of the first source and the first drain and also as one of the second source and the second drain.

7. The semiconductor device according to claim 6, further comprising:
a second impurity diffusion layer of the first conductivity type formed in the semiconductor layer; and
a third impurity diffusion layer of the second conductivity type formed in the semiconductor layer, wherein
the second impurity diffusion layer is the other of the first source and the first drain,
the third impurity diffusion layer is the other of the third source and the third drain,
the third impurity diffusion layer and the first impurity diffusion layer are electrically isolated from each other, and the third impurity diffusion layer and the second impurity diffusion layer are electrically isolated from each other.

8. The semiconductor device according to claim 6, further comprising:
a fourth impurity diffusion layer of the first conductivity type formed in the semiconductor layer; and
a fifth impurity diffusion layer of the second conductivity type formed in the semiconductor layer, wherein
the fourth impurity diffusion layer is the other of the second source and the second drain,
the fifth impurity diffusion layer is one of the third source and the third drain, and
the electrical connection between the fourth impurity diffusion layer and the fifth impurity diffusion layer is made with a compound layer of the semiconductor layer and metal formed continuously from the fourth impurity diffusion layer to the fifth impurity diffusion layer.
